(19) United States
(12) Patent Application Publication
(10) Pub. No.: US 2020/0149987 A1
(43) Pub. Date: May 14, 2020

(54) Method of Fabricating Flexible Pressure Sensors

(71) Applicants: Mohammed Jalal AHAMED, Windsor (CA); Simon RONDEAU-GAGNE, LaSalle (CA); Julia PIGNANELLI, LaSalle (CA); Tricia Breen CARMICHAEL, Windsor (CA)

(72) Inventors: Mohammed Jalal AHAMED, Windsor (CA); Simon RONDEAU-GAGNE, LaSalle (CA); Julia PIGNANELLI, LaSalle (CA); Tricia Breen CARMICHAEL, Windsor (CA)

(21) Appl. No.: 16/534,547

(22) Filed: Aug. 7, 2019

Related U.S. Application Data
(60) Provisional application No. 62/767,314, filed on Nov. 14, 2018.

(51) Int. Cl. G01L 9/00; B81C 99/00; B29C 37/00

(52) U.S. Cl. CPC G01L 9/0005; B81C 99/0085; B29K 2083/00; B29C 37/006; B29C 37/0053

(57) ABSTRACT

In a preferred embodiment, there is provided a method for preparing a capacitive pressure sensor, the sensor comprising a pair of conductive plate layers and a dielectric layer disposed therebetween, the dielectric layer comprising a dielectric polymer formed with a polymerization mixture fluid, wherein the method comprises placing the polymerization mixture fluid over a mold surface having a first three dimensional pattern thereon to form the dielectric polymer, thereby forming a second three dimensional pattern on a surface of the dielectric polymer complementary to the first three dimensional pattern.

### RELATED APPLICATIONS

This application claims the benefit under 35 USC 119(e) to U.S. Provisional Application Ser. No. 62/767,314 filed Nov. 14, 2018, the entire contents of which are incorporated herein by reference.

### FIELD OF THE INVENTION

This invention relates to a process for obtaining a pressure sensor, in particular a flexible pressure sensor, which includes a structured or microstructured polydimethylsiloxane (PDMS) dielectric layer disposed between two capacitor plate layers.

### BACKGROUND OF THE INVENTION

Pressure is a parameter that is commonly monitored in many biomedical and clinical applications, including for cardiovascular disease, intracranial pressure, pulmonary disease, and urinary and abdominal pressure. With an increase in demand for conformal pressure measurements, numerous flexible sensing technologies have been developed for biophysical pressure measurements. Among others, soft and flexible pressure sensors are gaining greater popularity because they are able to conform to the body and provide 3D sensing with higher deformability and conformability. Moreover, the ultrathin device dimensions of these sensors provide the potential for skin-like tactile sensitivity. Interestingly, flexible skin-inspired pressure sensors were used for cardiovascular monitoring, where high sensitivity is required to detect intermittent cardiac abnormalities through a wearable, flexible device. Other biomedical applications include measuring compression pressure in feet, and gait pressure during walking or rest. For all these examples, the sensors need to be optimized to enhance the sensitivity, as well as the pressure range, portability, and wearability.

Capacitive sensing is a commonly used method of detection pressure in many microsystems based sensors. In general, capacitive pressure sensors work by detecting changes in capacitance relative to the pressure applied. Specifically, two conductive plates separated by a dielectric medium can form a capacitor. Upon pressure, the distance between the two conducting plates of the capacitor is reduced, thus increasing the capacitance detected. This capacitance is governed by the equation (1): C=ε₀εᵣS/δ, where capacitance C depends on the following variables: ε₀ is the free, space permittivity, εᵣ is the relative permittivity, S is the area of the conducting plates and δ is the distance separating the plates. To design flexible and stretchable capacitor, a capacitance can be formed by sandwiching a flexible dielectric layer between two flexible electrodes. Upon pressure, the flexible dielectric layer deforms and creates changes in capacitance that can be sensed and calibrated to real pressure. However, most often, a non-structured dielectric cannot produce a significant deformation upon pressure, thus making it unsuitable for small area biophysical measurements. One way to overcome this issue can be through the incorporation of various micro-structures on the dielectric surface to reduce the elastic resistance and increase the flexibility, as well as to influence the effective dielectric constant of the dielectric layer. In such cases the incorporation of elastic micro-structures that deform with applied pressure increases the sensitivity of such devices.

The concept of increasing the capacitance-based sensitivity through dielectric microstructure incorporation is that when pressure is applied to the device, it is spread out across multiple structures. As a result, the pressure applied per structure is related to the deformation of the structure and therefore distance between the conductive plates of the device; hence capacitance recorded. The microstructured dielectric layer decreases the elastic resistance compared to non-structured dielectrics as a result of providing air gaps with which the structures deform which further increases the device sensitivity. Additionally, the incorporation of a PDMS structured dielectric increases the dielectric constant and thus the capacitance according to equation (1). Once the structures are compressed, the air voids are replaced by compressed PDMS structures which have a higher dielectric constant compared to air. More information on microstructured dielectrics and their role in capacitance device sensitivity has been previously reported in the literature.

Previous works have described the relationship between microstructure geometry on the dielectric layer relating with device sensitivity. For pyramid-shaped micro-structures, the angle of the pyramid base can influence the mechanical sensitivity. Greater pyramidal angles typically lead to greater sensitivity, which can be explained by the stress distribution of the higher angled pyramid-like structures. Additionally, the distance between the dielectric structures also plays a critical role in altering the stress distribution, where more space between structures lowers the stress distribution, increasing the compression of the dielectric structures. The height and shape of the dielectric structure also has a strong influence on the mechanical sensitivity in a capacitive pressure sensor.

Polydimethylsiloxane (PDMS) is commonly used as a dielectric within capacitance-based pressure sensors due its tunable elastic properties and compatibility with living cells and tissues. Multiple capacitive-based pressure sensors using microstructured PDMS have been recently reported, and have shown impressive sensitivity, measuring pressures less than 10 kPa. Various methods exist to create the micro-structures on the PDMS dielectric layer. A typical method used to create microstructures relies on photolithography, which, despite its high resolution and accuracy, requires time and high overhead equipment costs. One of the highest sensitivity reported from a photolithography-produced microstructured dielectric at low pressure regimes (p<0.2 kPa) is around 0.55 kPa. Another method that has been used to include a nanocomposite pattern in the PDMS dielectric has been demonstrated through direct laser cutting, where carbon nanotubes are patterned directly on the PDMS substrate. A recently developed method for elastomer microstructure incorporation utilizes a commercially available safety tape ribbon with embedded microstructured patterns, which is used as a template for mold fabrication. By casting and curing the PDMS over the tape microstructures, an inverse of the microscale features of the native tape is replicated in PDMS. Furthermore, the PDMS inverse pattern of the commercially available mold can subsequently be used as a mold to form the replica structures of the safety tape through surface treatment with perfluorinated octyltrichlorosilane (FOTS), allowing for the surface-anchored silane to act as a release layer for the replica structured PDMS. Although the above mentioned baseline methods are available for patterning microstructures on PDMS dielectric materials, there is currently no comparative study available to examine the sensitivities of each method.

### SUMMARY OF THE INVENTION

One possible non-limiting object of the present invention is to provide a method for obtaining a capacitive based pressure sensor, and which does not necessarily require expensive and labor intensive techniques, such as photolithographic techniques to provide a structured PDMS layer.

Another possible non-limiting object of the present invention is to provide a capacitive based pressure sensor providing for improved sensitivity at higher and/or lower pressure regimes, response time and/or flexibility, where the lower pressure regime is preferably defined to be between 0.5 kPa and 3 kPa, and the higher pressure regime is preferably defined to be between 3 kPa and 6 kPa.

In one aspect, the present invention provides a method for obtaining a capacitive based pressure sensor, the sensor comprising a pair of capacitor plate layers and a microstructured dielectric layer disposed therebetween, wherein the method comprises providing the capacitor plate layers and the microstructured dielectric layer, and disposing the dielectric layer between the capacitor plate layers, and wherein providing the microstructured dielectric layer comprises: i) pouring or disposing a mixture of a pre-polymer and optionally a crosslinking agent on a textured, structured or microstructured tape, and curing the mixture to obtain a cured mixture; and ii) removing or peeling the cured mixture from the tape, wherein the cured mixture forms the dielectric layer. In one embodiment, the cured mixture does not-form the dielectric layer, and providing the dielectric layer further comprises: ia) pouring or disposing a further mixture of a further pre-polymer and optionally a further crosslinking agent on the cured mixture, and curing the further mixture to obtain a further cured mixture; and ib) removing or peeling the further cured mixture from the cured mixture, wherein the further cured mixture forms the dielectric layer.

In another aspect, the present invention provides a method for preparing a capacitive pressure sensor, the sensor comprising a pair of conductive plate layers and a dielectric layer disposed therebetween, the dielectric layer comprising a dielectric polymer formed with a polymerization mixture fluid, wherein the method comprises placing the polymerization mixture fluid over a mold surface having a first three dimensional pattern thereon to form the dielectric polymer, thereby forming a second three dimensional pattern on a surface of the dielectric polymer complementary to the first three dimensional pattern.

In yet another aspects the present invention provides a capacitive pressure sensor comprising a pair of conductive plate layers and a dielectric layer disposed therebetween, the dielectric layer comprising a polydimethylsiloxane polymer and the conductive plate layers each comprising a polydimethylsiloxane polymer plate, wherein the dielectric layer is prepared with a method comprising placing a polymerization mixture fluid over a mold surface having a first three dimensional pattern thereon to form the polydimethylsiloxane polymer, thereby forming a second three dimensional pattern on a surface of the polydimethylsiloxane polymer complementary to the first three dimensional pattern, and wherein one of the first and second three dimensional patterns comprises a plurality of projections or pyramidal projections extending substantially normal to the mold surface or the surface of the polydimethylsiloxane polymer, and the other one of the first and second three dimensional patterns is shaped for forming the projections or pyramidal projections.

In yet another aspect, the present invention provides a capacitive pressure sensor comprising a pair of conductive plate layers and a dielectric layer disposed therebetween, the dielectric layer comprising a polydimethylsiloxane polymer and the conductive plate layers each comprising a polydimethylsiloxane polymer plate, wherein the dielectric layer is prepared with a method comprising placing a polymerization mixture fluid over a mold surface having a first three dimensional pattern thereon to form the polydimethylsiloxane polymer, thereby forming a second three dimensional pattern on a surface of the polydimethylsiloxane polymer complementary to the first three dimensional pattern, and wherein one of the first and second three dimensional patterns comprises a plurality of projections extending substantially normal to the mold surface or the surface of the polydimethylsiloxane polymer, and the other one of the first and second three dimensional patterns is shaped for forming the projections.

In one embodiment, the capacitor or conductive plate layer comprises a polysiloxane polymer, preferably a metalized polydimethylsiloxane (PDMS) polymer, wherein each said capacitor or conductive plate layer are of generally equal size and thickness. In one embodiment, the capacitor or conductive plate layer includes the metalized PDMS polymer formed by curing a mixture of a pre-polymer or pre-polymer mixture and a crosslinking agent at a weight ratio of between about 5:1 and about 40:1, preferably between about 10:1 and about 30:1 or more preferably about 20:1. In one embodiment, the capacitor or conductive plate layer comprises multiple stripes of metallic or electrically conductive tape oriented generally parallel to one another, wherein the metallic tape is preferably a copper tape. In one embodiment, the stripes of the metallic or electrically conductive-tape included in one said capacitor or conductive plate layer are oriented generally perpendicular to those of other said capacitor or conductive plate layer.

In an alternative embodiment, the electrode material or capacitor or conductive plate layer comprises copper tape, PEDOT:PSS, silver nanowires, elements such as gold, Cu, Mg, Fe etc. (evaporation) or carbon nanotubes. In one embodiment, the capacitor or conductive plate layer and/or the dielectric layer comprises a self-healing polymer.

In one embodiment, the conductive plate layers each comprises a polydimethylsiloxane polymer plate, wherein the polydimethylsiloxane polymer plate preferably has a plurality of generally parallel elongate conductive tapes coupled thereto, and wherein the conductive plate layers are oriented relative to each other to place the conductive tapes coupled to one of the polydimethylsiloxane polymer plate generally orthogonal to the conductive tapes coupled to the other one of the polydimethylsiloxane polymer plate. In one embodiment, the polydimethylsiloxane polymer plate is coated with poly(3,4-ethylenedioxythiophene) polystyrene sulfonate (PEDOT:PSS), and the dielectric layer is plasma sealed to the conductive plate layers.

In one embodiment, the method further comprises placing the dielectric layer between the conductive plate layers, wherein each said conductive plate layer comprises a polydimethylsiloxane polymer plate having a plurality of generally parallel elongate conductive tapes coupled thereto, and wherein the conductive plate layers are oriented relative to each other to place the conductive tapes coupled to one of the polydimethylsiloxane polymer plate generally orthogonal to the conductive tapes coupled to the other one of the polydimethylsiloxane polymer plate. In one embodiment, the polydimethylsiloxane polymer plate is coated with poly(3,4-ethylenedioxythiophene) polystyrene sulfonate (PEDOT:PSS), said method further comprising plasma sealing the dielectric layer to the conductive plate layers.

In one embodiment, the mold surface is provided by an adhesive tape having the first three dimensional pattern thereon, the method further comprising dissolving or removing an adhesive portion of the adhesive tape prior to said placing the polymerization mixture fluid over the mold surface.

In one embodiment, the tape is an adhesive tape or a safety reflective tape, and providing or forming the dielectric layer further comprises dissolving an adhesive portion of the tape in a solvent, preferably an organic solvent, such as, but not limited to, diethyl ether, ethanol, acetone, acetonitrile, butanol, chloroform, chlorobenzene, 1,2-dichloromethane or tetrahydrofuran, for a period between 1 and 48 hours, preferably between 3 and 30 hours or more preferably about 12 hours. Preferably, placing, pouring or disposing the mixture or the polymerization mixture fluid comprises pouring or disposing the mixture or the fluid on a textured, structured or microstructured surface of the tape or the cured mixture.

It is to be appreciated that the adhesive tape may be any commercially available safety tape, provided that the tape has the first or third three dimensional pattern, most preferably having or operable to provide the structure shown in FIGS. 5 to 8 or as described herein, including those described in Table 1. The surface structure of a suitable adhesive tape may be determined using for example optical microscopy or scanning electron microscopy. A preferred, non-limiting commercially available safety tape may include red/white safety reflective tape available from Starrey <https://www.amazon.com/X4yard-Waterproof-self-adhesive-tape-reflective-Conspicuity-reflectante/dp/B01MU2LLIF/ref=lp_3430087011_1_3?s=industrial&ie=UTF8&qid=1565184959&sr=1-3>.

It has been appreciated that the dielectric layer obtained with the method of the present invention may itself be used to provide the mold surface, such that a further dielectric layer to be formed with the mold surface provided by the dielectric layer may be used to form the capacitive pressure sensor. This is alternative to a preferred embodiment, where a tape is used as the mold surface. Hereinbelow, the dielectric layer obtained with the method where a tape is preferably used to provide the mold surface is referred as having “inverse” structure or microstructure, whereas the dielectric layer obtained with that dielectric layer preferably obtained with the tape as the mold surface is referred as having “direct” or “replica” structure or microstructure.

In this regard, in one embodiment, the mold surface is provided by an adhesive tape having the first three dimensional pattern thereon, the method further comprising dissolving or removing an adhesive portion of the adhesive tape prior to said placing the polymerization mixture fluid over the mold surface. In an alternative embodiment, the mold surface is provided by a polymeric mold formed by placing a second polymerization mixture fluid over an adhesive tape having a third three dimensional pattern thereon, an adhesive portion of the adhesive tape having been removed or dissolved prior to said placing the second polymerization mixture fluid over the adhesive tape, wherein the third three dimensional pattern is shaped for forming the first three dimensional pattern. It is to be appreciated that the second polymerization mixture fluid may be the same or different from the polymerization mixture fluid. The second polymerization mixture fluid is not strictly required to produce a specific polymer, provided that the polymer can operate to function as the polymeric mold.

In one embodiment, the second polymerization mixture fluid is cured over the adhesive tape at a curing temperature between about 40° C. and about 80° C. for between about 30 minutes and 4 hours to form the polymeric mold, and the polymeric mold is subject to vapor deposition of perfluorooctyltrichlorosilane (FOTS) prior to said placing the polymerization mixture fluid over the mold surface.

In one embodiment, the dielectric layer and/or the conductive plate layer comprises a polysiloxane polymer. Preferably, the polysiloxane polymer comprises one or more metal-coordinating units selected to coordinate or chelate with an iron, iron ion or iron salt. In one embodiment, the polysiloxane polymer comprises a PDMS polymer. It has been appreciated that the polysiloxane polymer mixed with an iron salt may be more robust for use in creating a patterned dielectric layer and/or self-healing, (spontaneous regeneration) after damage. In one embodiment, the mixture or further mixture comprises the pre-polymer and the crosslinking agent with a weight ratio of the pre-polymer and the crosslinking agent being between about 1 and 80, preferably between about 5 and 40, more preferably between about 10 and 30 or most preferably about 20.

In one embodiment, the dielectric polymer comprises a crosslinked polydimethylsiloxane polymer, and the polymerization mixture fluid comprises a pre-polymer mixture comprising at least one or more silicon monomers, and a crosslinking agent selected for crosslinking a linear polydimethylsiloxane polymer to form the crosslinked polydimethylsiloxane polymer, wherein the weight ratio of the pre-polymer mixture to the crosslinking agent in the polymerization mixture fluid is between about 10:1 and about 30:1 or preferably about 20:1. In one embodiment, said method further comprises curing the polymerization mixture fluid over the mold surface at a curing temperature between about 40° C. and about 80° C. for between about 30 minutes and 4 hours. In one embodiment, the method further comprises degassing the polymerization mixture fluid in a vacuum desiccator prior to said curing the polymerization mixture fluid, and after said curing the polymerization mixture fluid, the method further comprises removing or peeling the dielectric polymer from the mold surface.

In one embodiment, the pre-polymer mixture and/or the crosslinking agent may be any commercially available product, provided that the product is operable to provide a mixture or the polymerization mixture fluid to most preferably form the crosslinked polydimethylsiloxane polymer. By way of non-limiting examples, the commercially available product may be purchased from Gelest Inc., Morrisville, Pa.

In one embodiment, the dielectric layer comprises on a surface a plurality of projections extending generally normal to the surface. In one embodiment, the projection has a pyramidal or frustoconical shape, preferably a triangular pyramidal or frustoconical shape.

In one embodiment, one of the first and second three dimensional patterns comprises a plurality of projections or pyramidal projections extending substantially normal to the mold surface or the surface of the dielectric polymer, and the other one of the first and second three dimensional patterns is shaped for forming the projections or pyramidal projections. In one embodiment, each said pyramidal projection has a generally triangular pyramid shape having a peak, wherein a peak height of the triangular pyramid shape is between about 80 μm and about 160 μm, a base width of the triangular pyramid shape is between about 160 μm and 240 μm, and/or a distance between two said triangular pyramid shapes is between about 160 μm and 240 μm. In one embodiment, the other one of the first and second three dimensional patterns shaped for forming the pyramidal projections has a structure height between about 40 μm and about 120 μm, a base width between about 80 μm and 170 μm, and/or a distance between peaks between 140 μm and 220 μm.

In one embodiment, one of the first and second three dimensional patterns is substantially shaped as shown in FIGS. 5 and 6, and the other one of the first and second three dimensional patterns is substantially shaped as shown in FIGS. 7 and 8.

In one embodiment, the method further comprises, after the pouring/disposing step, placing the mixture in an environment degassed by a vacuum desiccator. In one embodiment, the curing step comprises curing the mixture at a temperature between 5° C. and 120° C., preferably between 10° C. and 80° C. or more preferably between 20° C. and 70° C. for between 30 minutes and 96 hours, preferably between 1 and 60 hours or more preferably between 2 and 48 hours. In one embodiment, the curing step comprises curing the mixture at about 60° C. for about 2 hours, or at about 25° C. for about 48 hours.

In one embodiment, providing the dielectric layer further comprises exposing the cured or further cured mixture to 02 plasma and optionally subjecting the cured mixture to perfluorooctyltrichlorosilane (FOTS) treatment, as for example described in I. W. Moran, et al, High-resolution soft lithography of thin film resists enabling nanoscopic pattern transfer, Soft Matter. 4 (2007) 168-176, the contents of which are incorporated herein by reference.

In one embodiment, the method comprises depositing conductive materials (metallic film or conducting polymer) on a soft substrate, and sandwiching the pre-patterned dielectric material between the two conducting plates to create the pressure sensor.

It has been appreciated that the patterning of the sensing layer or the dielectric layer may be performed by molding soft materials (such as siloxane-based, healable or non-healable materials) directly on a commercial tape (such as safety reflective tape), containing a plurality of tetrahedral motifs. In one embodiment, providing the dielectric layer comprises pouring the polymer over a surface of the tape and curing the polymer at 60° C. or crosslinking with a metal salt for 48 hours. In one embodiment, the method further comprises peeling or removing the cured polymer from the tape to produce an inverse tape structure or microstructure.

In one embodiment, the method comprises preparing the PDMS by mixing 20 parts elastomer and 1 part curing agent to form a polymer, and curing the polymer within an epoxy mold that incorporates a micropattern-like design on a tape or an adhesive tape. In one embodiment, the tape is a commercially available tape (Jogslite, Silver Lake, N.H.) or safety reflective tape. In one embodiment, the method further comprises placing the polymer and the tape in a vacuum for about one hour at room temperature and curing for about 24 hours at room temperature.

It has been appreciated that flexibility of the sensor may constitute an important parameter related to sensor sensitivity, and flexibility may be measured by measuring the modulus of elasticity. Some embodiments of the present invention has been tested and shown to include with rough structured or microstructured PDMS modulus to be 1.29 MPa, to be compared to non-structured PDMS modulus which was found to be 2.90 MPa. The difference in moduli was not determined to be significant or substantial since the structures are not changing the material property of PDMS.

In one embodiment, the method further comprises plasma treatment to seal a flat side of the dielectric layer to the base electrode or capacitor plate layers. In one embodiment, the method further comprises plasma treatment to seal the top electrode or one said capacitor plate layer to outside edges of the bottom electrode or other said capacitor plate layer (combined with the dielectric layer). In one embodiment, the method further comprises attaching wires to the bottom and top electrode or said capacitor plate layers, preferably by silver paste adhesion directly on the electrode side.

It is to be appreciated that the tape itself may not be used as a mold, and the tape may be removed via scalpel to expose the microstructure like molding. In one embodiment, the tape is a double sided tape which is taped to a glass slide which is then coated with the mixture of the pre-polymer and optionally the crosslinking agent. It is to be further appreciated that two structures may be presented from the mold—replica and inverse structures which are produced from different methods—one of which (replica) is may be prepared through plasma and perfluorosilane treatment—as may be similar to a standard procedure often done for PDMS. The other may involve simply peeling off from the tape mold (inverse).

Additional and alternative features of the present invention will be apparent to a person skilled in the art from the following detailed description of the preferred embodiments thereof.

### BRIEF DESCRIPTION OF THE DRAWINGS

Reference may now be had to the following detailed description taken together with the accompanying drawings in which:

FIG. 1 shows a perspective exploded view of a flexible capacitance based pressure sensor in accordance with a preferred embodiment of the present invention;

FIG. 2A shows a surface image of a fabricated PDMS dielectric layer to be included in the pressure sensor shown in FIG. 1;

FIG. 2B shows another surface image of a fabricated PDMS dielectric layer to be included in the pressure sensor shown in FIG. 1;

FIG. 3A shows a perspective image of an assembled device which includes the pressure sensor shown in FIG. 1;

FIG. 3B shows another perspective image of an assembled device which includes the pressure sensor shown in FIG. 1;

FIG. 4A shows a scheme for preparing replica and inverse tape ribbon molds of a dielectric PDMS layer to be included in the pressure sensor shown in FIG. 1;

FIG. 4B shows three schemes a) to c) respectively for producing a photolithographic structure, an inverse structure and a direct or replica structure, as well as the scanning electron micrographs of the corresponding structures (far right hand side);

FIG. 5 shows a scanning electron micrograph of an inverse tape molded microstructure at a 0-degree angle overview with 240× magnification to be used in a method for preparing a flexible capacitance based pressure sensor in accordance with a preferred embodiment of the present invention;

FIG. 6 shows a scanning electron micrograph of the inverse tape molded microstructure shown in FIG. 5 at a 60-degree angle overview with 240× magnification;

FIG. 7 shows a scanning electron micrograph of a replica tape molded microstructure at a 0-degree angle overview to be used in a method for preparing a flexible capacitance based pressure sensor in accordance with a preferred embodiment of the present invention;

FIG. 8 shows a scanning electron micrograph of the replica tape molded microstructure shown in FIG. 7 at a 60-degree angle overview;

FIG. 9 shows a scanning electron micrograph of a photolithographic structure at a 0-degree angle overview of a dielectric PDMS layer to be included in a comparative flexible capacitance based pressure sensor;

FIG. 10 shows a scanning electron micrograph of the photolithographic structure shown in FIG. 10 at a 60-degree angle overview;

FIG. 11 shows a line graph showing a stress (y-axis) vs. strain (x-axis) plot for two non-structured 20:1 PDMS samples respectively cured at 25° C. and 60° C.;

FIG. 12 shows a line graph showing a stress (y-axis) vs. strain (x-axis) plot for non-structured and structured 20:1 PDMS samples cured at 60° C.;

FIG. 13 shows a line graph showing a stress (y-axis) vs. strain (x-axis) plot for non-structured and structured 20:1 PDMS samples cured at 25° C.;

FIG. 14 shows a graph illustrating pressure sensitivity of a flat PDMS sample without any patterned structures, where-average change in capacitance was recorded over five trials per pressure applied per device using an Agilent Handheld LCR meter, and where the dotted lines were used to calculate the slope representing sensitivity;

FIG. 15 shows a graph illustrating pressure sensitivity of a structured PDMS sample prepared with inverse molding of tape surface, where average change in capacitance was recorded over five trials per pressure applied per device using an Agilent Handheld LCR meter, and where the dotted lines were used to calculate the slope representing sensitivity;

FIG. 16 shows a graph illustrating pressure sensitivity of a structured PDMS sample prepared with replica tape ribbon, where average change in capacitance was recorded over five trials per pressure applied per device using an Agilent Handheld LCR meter, and where the dotted lines were used to calculate the slope representing sensitivity;

FIG. 17 shows a graph illustrating pressure sensitivity of a structured PDMS sample prepared with photolithography, where average change in capacitance was recorded over five trials per pressure applied per device using an Agilent Handheld LCR meter, and where the dotted lines were used to calculate the slope representing sensitivity;

FIG. 18 shows a graph illustrating a relationship between lower pressure detection sensitivity and dielectric structure base width;

FIG. 19 shows a graph illustrating a relationship between lower pressure detection sensitivity and peak separation;

FIG. 20 shows a graph illustrating a relationship between higher pressure detection sensitivity and dielectric structure base width;

FIG. 21 shows a graph illustrating a relationship between higher pressure detection sensitivity and peak separation;

FIG. 22 shows a graph illustrating a relationship between low pressure detection sensitivity and dielectric structure height;

FIG. 23 shows a graph illustrating a relationship between higher pressure detection sensitivity and dielectric structure height;

FIG. 24A shows on the left side a line graph illustrating the results of a dynamic capacitance testing, and which includes on the y-axis normalized capacitance and on the x-axis time in seconds, and on the right side an image illustrating the dynamic capacitance testing, where a 50 g weight was placed on an inverse mold dielectric sensor and removed from the sensor every 2 seconds for 6 cycles, and capacitance was recorded every 2 seconds;

FIG. 24B shows a line graph illustrating the results of a dynamic capacitance testing, and which includes on the y-axis normalized capacitance and on the x-axis time in seconds, where in the testing, a 50 g weight was placed on an inverse mold dielectric sensor and removed from with capacitance recorded every 15 ms for 7 cycles;

FIG. 25 shows a top image of a shoe with an inverse structured dielectric sensor applied to the sole thereof for recoding of the sensor response during walking;

FIG. 26 shows a line graph illustrating the results of a dynamic capacitance testing of the sensor shown in FIG. 27, and which includes on the y-axis normalized capacitance at differing pressure distributions and on the x-axis time in seconds; and

FIG. 27 shows a scheme for a method in accordance with a preferred embodiment of the present invention.

### DETAILED DESCRIPTION OF THE PREFERRED EMBODIMENTS

The following preferred, non-limiting embodiments relates to the fabrication, characterization and comparative study of flexible pressure sensors, prepared from structured polydimethylsiloxane (PDMS) as flexible dielectric. In specific, four different patterning methods on PDMS dielectric surface were investigated, including inverse mold, replica mold, photolithographic and non-shaped microstructures. The different patterned dielectrics were compared to gain insight onto the effect of flexible microstructure design on pressure sensitivity. A complete material characterization was performed using optical microscopy, scanning electron microscopy and tensile testing to evaluate the physical and electrical properties of the different microstructured PDMS dielectric. Static and dynamic pressure measurements were also performed to determine pressure sensitivities. Our results showed a strong dependence of the pressure sensitivity versus the patterning method utilized. Dielectric patterned from a simple tape molding procedure showed increased sensitivity at higher pressure regimes (p>3 kPa) compared to the photolithographic structured dielectric. The inverse dielectric structures produced a higher sensitivity at pressures less than 3 kPa. This work gives new tools to achieve desired pressure sensitivities in flexible polymer-based sensors, especially for pressures ranging several kPa. The comparative analysis presented in this paper will aid further development of flexible sensors with various tactile sensitivities.

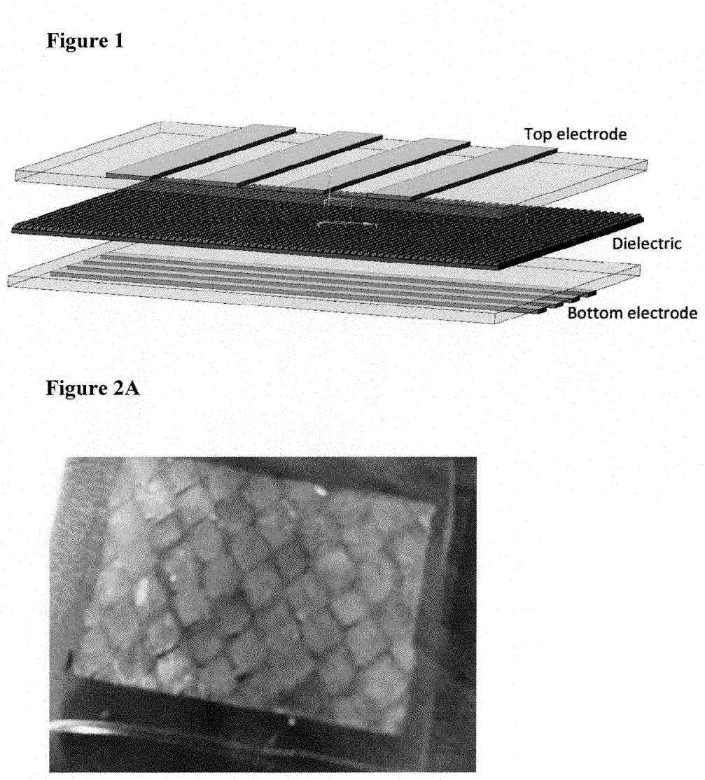

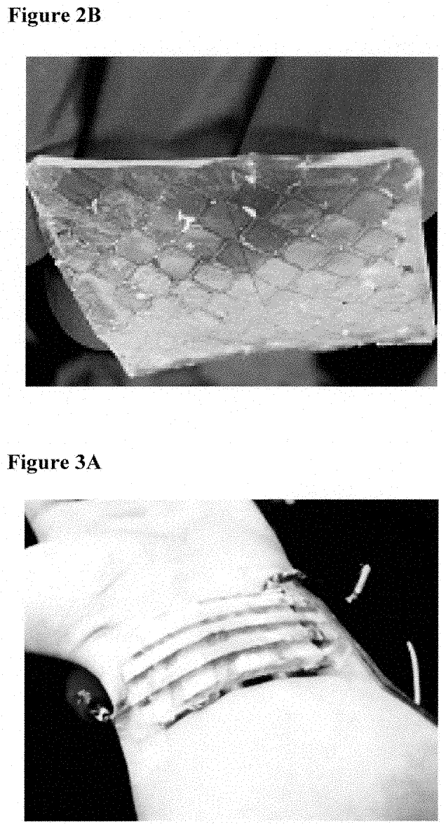

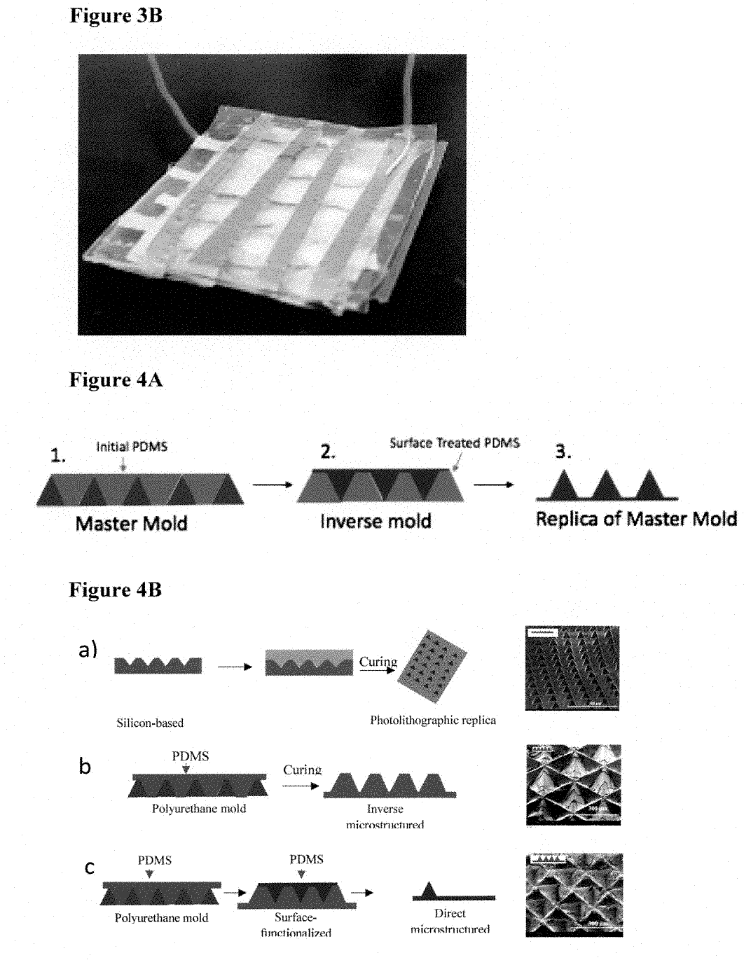

Reference is made to FIG. 1 which shows the design of a flexible pressure sensor in accordance with a preferred embodiment of the present invention, and which has a polydimethylsiloxane (PDMS) dielectric layer or spacer layer and a pair of opposed top and bottom flexible electrode layers. The top and bottom electrode layers operate as top and bottom parallel plates of a capacitor with two pieces of metalized PDMS of equal size and thickness, as shown in FIG. 1. As best seen in FIGS. 2A and 2B, the pressure sensor may preferably be prepared with the PDMS dielectric spacer layer configured as a patterned PDMS dielectric layer. For construction, the PDMS dielectric layer is sandwiched between two metalized flat PDMS layers forming the capacitor, and the metallized version of the flexible capacitor is shown in FIGS. 3A and 3B.

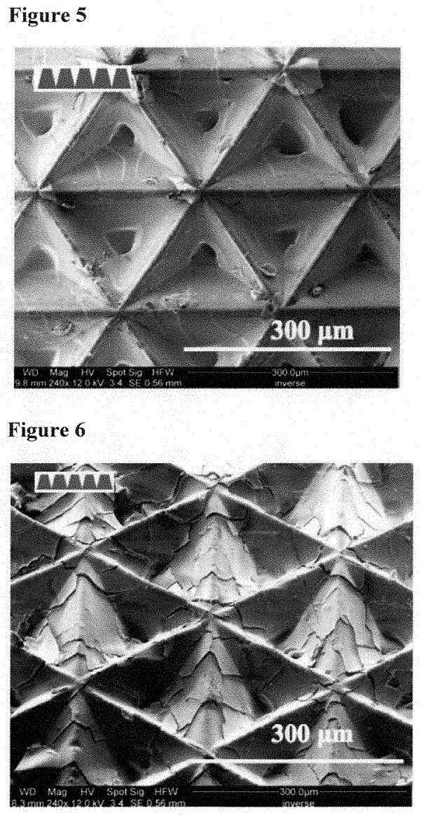

For comparison purposes, as noted above, four different constructions of the PDMS dielectric layer were prepared, including: (i) flat surface non-structured PDMS layer, (ii) microstructured PDMS layer patterned from lithography, (iii) inverse microstructured PDMS layer patterned from tape-based molding and (iv) microstructured PDMS layer with replica structure patterning from the tape-based master mold. A scheme showing the procedure used for micropatterning is shown in FIGS. 4A and 4B. All methods used for preparing the PDMS layers involved standard PDMS mold transfer, and the dielectric structured through photolithography was prepared following previously reported procedure as described in S. C. B. Mannsfeld, et al, Highly sensitive flexible pressure sensors with microstructured rubber dielectric layers, Nat. Mater. 9 (2010) 859-864, the contents of which are incorporated herein by reference.

In the photolithographic mold transfer process, a mold was prepared on a silicon substrate by standard semiconductor fabrication process using photolithography and wet etching, as for example described in H. H. Chou, et al, A chameleon-inspired stretchable electronic skin with interactive colour changing controlled by tactile sensing, Nat. Commun. 6 (2015) 1-10, the entire contents of which are incorporated herein by reference. This process uses well defined silicon etching process parameters and requires a cleanroom facility equipped with lithography facility and is expensive compared to the other processes in the comparison. Alternatively, photolithography was used to transfer the pattern on to a silicon wafer. The photoresist mask was then hard baked to create an etch mask. The silicon wafer was then wet etched to patterns on the silicon, afterwards the mask is stripped off and cleaned to finalize the mold fabrication. PDMS was poured on top of the mold, cured and peeled-off to create the microstructures on the PDMS.

Three steps were used to replicate the tape structures into a PDMS dielectric layer. First, the adhesive portion of the tape was dissolved in diethyl ether overnight. Second, the 20:1 ratio of pre-polymer (10 g) to crosslinking agent (0.5 g) PDMS was poured on top of the tape ribbon, degassed in a vacuum desiccator, and then cured at either 60° C. for two hours or 25° C. for 48 hours. The cured PDMS was then peeled off from the tape ribbon to produce the inverse tape structure, and then exposed to O₂ plasma for 1 minute at a pressure of 10 psig (flow rate 10.6 mL/min.) followed by vapor deposition of perfluorooctyltrichlorosilane (FOTS) for 1 hour in a vacuum desiccator, as for example described in I. W. Moran, et al, High-resolution soft lithography of thin film resists enabling nanoscopic pattern transfer, Soft Matter. 4 (2007) 168-176, the entire contents of which are incorporated herein by reference. This provided a release layer on the inverse tape ribbon structured PDMS to be used as a mold to produce a replica molding master structure. The photolithographic-microstructured dielectric layer was fabricated using previously reported procedures and imaged in order to quantify the differences in structure sizes between the photolithographic method and inverse and replica master molded method in accordance with a preferred embodiment of the invention, in a view of S. C. B. Mannsfeld, et al, Highly sensitive flexible pressure sensors with microstructured rubber dielectric layers, Nat. Mater. 9 (2010) 859-864, the entire contents of which are incorporated herein by reference.

Once the dielectric layers were fully cured, they were assembled into a capacitive device, and used as the dielectric. Each device used metalized PDMS (20:1) as the top and bottom plates of the capacitance-based sensor, imparting flexibility to the entire device. Copper tape was used to provide conductivity to the elastomeric plates, where stripes of tape were placed longitudinally and vertically on the top relative to the bottom plate to produce multiple capacitance sites along the sensor to improve sensitivity. The PDMS dielectric layer was then placed and secured between the two plates of the capacitor as illustrated in FIG. 1.

It has been envisioned that the pressure sensor of the invention may permit increased sensitivity through, for example, decreasing the elastic resistance and/or increasing the dielectric constant of the device, while allowing for production by a less complex or costly fabrication process.

### A. Material Characterization

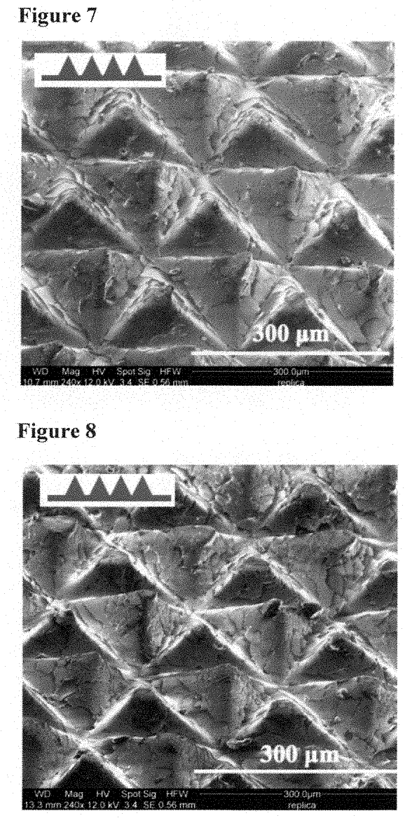

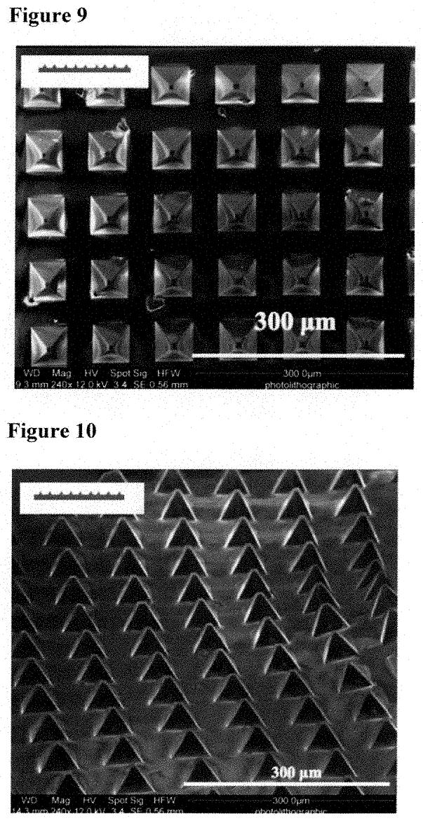

First, PDMS dielectric structures were characterized using optical microscopy and scanning electron microscopy (SEM) to reveal the size and distribution of the microstructures incorporated onto the surface of the dielectric layers. Samples were initially coated with few nanometers of gold for visualization to provide the polymer with good conductivity for SEM. The size and distribution of the microstructures were compared to correlate device sensitivity with the arrangement of the microstructures, and the results are summarized in Table 1 below. As observed by SEM shown in FIGS. 5 and 6, the inverse structures, showed triangular depressions proportionate to the replica tape ribbon peaks, with approximate base widths, measured from the depression of one structure to the adjacent, of 128 Jim, separations between peaks of 182 μm and structure heights of 80 μm. As seen in FIGS. 7 and 8, the replica tape ribbon structures showed triangular based pyramids with base width of approximately 197 μm with 208 μm separation between peaks and with 120 μm structure heights. The photolithographic structures showed square based pyramids with a 53 μm width, 94 μm peak separation and 46 μm structure height, as seen in FIGS. 9 and 10.

TABLE 1
Summary of Dielectric Structure Size,
Distribution and Device Sensitivity

| | | | | | Sensi- | Sensi- |
|---|---|---|---|---|---|---|
| | | Struc- | | Distance | tivity | tivity |
| | | ture | Base | between | 0.5 kPa < | 3 kPa < |
| Dielectric | Base | Height | Width | peaks | p < 3 kPa | p < 6kPa |
| structure | shape | (μm) | (μm) | (μm) | (kPa⁻¹) | (kPa⁻¹) |
| Non- | N/A | N/A | N/A | N/A | 0.0353 | 0.0078 |
| Structured | | | | | | |
| Inverse | Triangle | 80 | 128 | 182 | 0.172 | 0.0569 |
| tape mold | | | | | | |
| structured | | | | | | |
| Replica | Triangle | 120 | 197 | 208 | 0.094 | 0.7298 |
| tape mold | | | | | | |
| structured | | | | | | |
| Photo- | Square | 46 | 53 | 94 | 0.1851 | 0.0373 |
| lithographic | | | | | | |
| structured | | | | | | |

### B. Tensile Testing Analysis

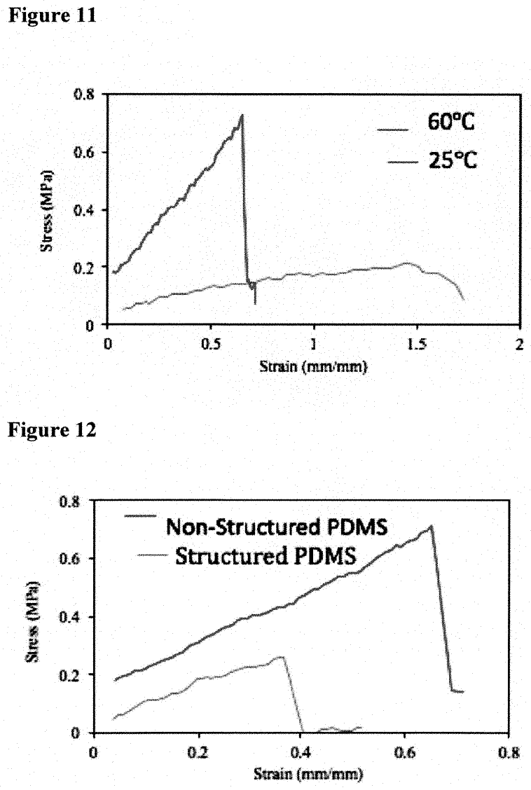

To characterize the mechanical flexibility of the dielectric in the capacitance-based pressure sensors, tensile testing was performed. Samples subjected to the tensile test were prepared, and either poured and cured on a Petri dish containing no molding tape or on a microstructured tape ribbon mold as seen in FIGS. 4A and 4B. Curing temperature and time was, varied either at 25° C. for 48 hours or at 60° C. for 2 hours. Once cured, the samples were cut into equal sized rectangles with an average width of 15 mm, length of 35 mm, and thickness of 1.7 mm. These samples were then subjected directly to a tensile test with a test rate of 2 mm/s. The stress vs. strain plots were obtained from the crosshead and load data, for either structured or non-structured samples as shown in FIGS. 11 to 13.

The Young's modulus of non-structured PDMS samples cured at 60° C. was found to be 810 kPa, and in comparison, the samples cured at 25° C. showed an average Young's modulus of 110 kPa. The higher Young's moduli for samples cured at 60° C. is in good agreement with the relationship between elasticity and curing temperature. The 60° C. curing temperature may be selected in order to ensure a higher Young's modulus as opposed to room temperature (25° C.) curing to provide a stiffer material to be subjected to the pressure applied. The reasoning behind possibly wanting the Young's modulus to be higher is that as the value increases, the more rigid the material and therefore more likely that it will return to its original shape after deformation. This may be valuable to consider since the principle behind capacitance-based pressure sensing depends upon the distance change between plates of a capacitor which in this case contains the microstructured dielectric.

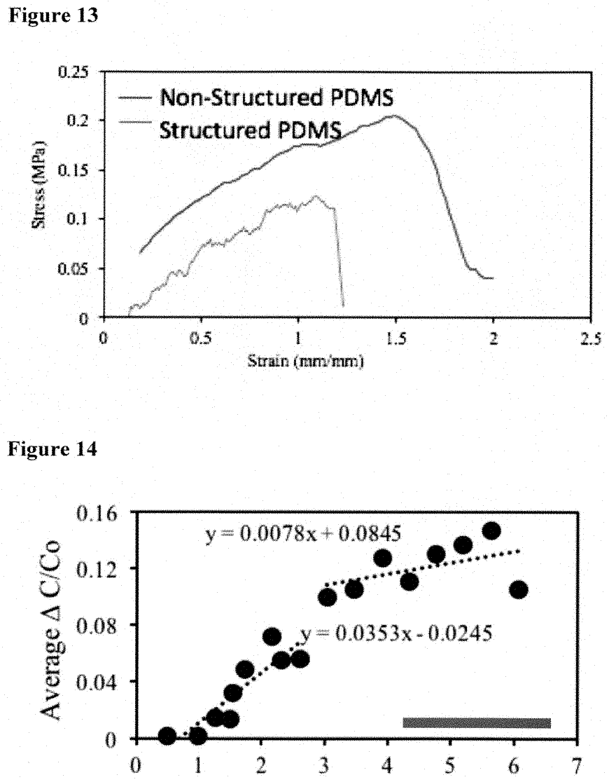

The maximum strain resistance was found to be higher for non-structured samples in comparison to structured samples, at both 60° C. and 25° C. (FIGS. 12 and 13), which can be attributed to the introduction of defects during patterning. The strain values were determined in order to characterize the elasticity of the PDMS composing the electrodes and dielectric in order to attribute the elasticity of the materials to the mechanical compression upon pressure applied. Optimization of the polymer fabrication was confirmed through, tensile testing to determine the efficient curing temperature, and optimal compression relative to the pressure applied. Samples cured at 60° C., which showed a larger Young's modulus, were considered to be more likely to deform proportionally to the pressure applied, thus having a better sensitivity toward low pressures in capacitive devices.

### C. Sensor Characterization

The sensors were characterized for a range of applied pressures to investigate the change in capacitance in response to different static pressure. A known calibration mass was placed on top of the sensor to measure capacitance before and after applied load. For each sensor, the sensing area was measured in order to calculate the effective pressure acting on the sensor. Capacitance data was collected through a capacitance meter, where initial and changed capacitance values were recorded before and after the standardized weights were applied. The applied pressure ranged from approximately 0.5 kPa to 6 kPa, according to the range of standardized weights from 1 to 50 g. Five trials were performed per device, per pressure applied, and changes in capacitance with applied pressure were analyzed. Sensors' sensitivity was determined by calculating the slope of the curve at different pressure ranges (from 0.5 kPa<p<3 kPa and 0.5<p<6 kPa). Additionally, a dynamic test was performed to confirm the devices' ability to respond in real time.

Devices were tested and subjected to a range of pressures ranging from 0.5 kPa to 6 kPa to determine their sensitivity at higher (3 kPa<p<6 kPa) and lower (0.5 kPa<p<3 kPa) pressure regimes. The PDMS structures varied from a non-structured, an inverse master mold structured, a replica master mold structured, and a photolithographic-structured dielectric. For each type of dielectric, five trials per pressure applied was recorded per device in order to obtain an average percent change in capacitance versus pressure applied curve, as shown in FIGS. 14 to 17. The non-structured dielectric device showed a sensitivity of 0.0353 kPa⁻¹ for pressures of 0.5 kPa to approximately 3 kPa and 0.0078 kPa⁻¹ for pressures of approximately 3 kPa to 6 kPa. In comparison, the inverse ribbon tape structured dielectric showed a sensitivity of 0.172 kPa⁻¹ for pressures between 0.5 kPa and 3 kPa and 0.0569 kPa⁻¹ for pressures between 3 kPa and 6 kPa. The replica ribbon tape structured dielectric showed the highest sensitivity at pressures between 3 kPa and 6 kPa with a value of 0.7298 kPa⁻¹. At pressures between 0.5 kPa and 3 kPa, the replica ribbon tape structured dielectric showed a sensitivity of 0.094 kPa⁻¹. Lastly, the dielectric PDMS layer structured by photolithography showed a sensitivity of 0.1851 kPa⁻¹ at pressures between 0.5 kPa and 3 kPa and a sensitivity of 0.0375 kPa⁻¹ at pressures between 3 kPa and 6 kPa. The results are summarized in Table 1 shown above.

Compared to the different structured dielectrics, the non-structured sample showed low sensitivity of pressure detection at both higher (3 kPa<p<6 kPa) and lower pressures (0.5 kPa<p<3 kPa). This can be explained by the lack of asperities on the dielectric surface to distribute the pressure and cause changes in the distance between the two plates. Sensitivities were compared against the non-structured, which was used as benchmark (Table 2). Compared to the different structured dielectrics, the non-structured sample showed low sensitivity of pressure detection at both higher (3 kPa<p<6 kPa) and lower pressures 0.5 kPa<p<3 kPa). This can be explained by the lack of asperities on the dielectric surface to distribute the pressure and cause changes in the distance between the two plates. Sensitivities were compared against the non-structured which was used as benchmark (Table 2). Devices made with inverse tape ribbon molded PDMS dielectric showed similar pressure sensitivity at lower pressures (0.5 kPa<p<3 kPa) to devices made with PDMS dielectric structured by photolithography compared with the non-structured. Referring to Table 2, with photolithography the sensitivity at lower pressure (S₁) increased by 5.24 times whereas with inverse mold it increased by 4.78 times. At higher pressures (3 kPa<p<6 kPa), the inverse and replica PDMS structured dielectric devices showed higher sensitivity (S₂) compared to the photolithographic PDMS dielectric, with 7.29 and 93.56 times increase, respectively, as tabulated in Table 2.

TABLE 2
Differences in sensitivity of the devices made with inverse and replica
tape ribbon structured dielectrics, and photolithographic structured dielectric.

| | Sensitivity (S₁) | Sensitivity (S₂) | Sensitivity (S₁) | Sensitivity (S₂) |
|---|---|---|---|---|
| | from 0.5 to 3 kPa | from 3 to 6 kPa | increase | increase |
| Dielectric | pressure range | pressure range | compared to | compared to |
| structure | (kPa⁻¹) | (kPa⁻¹) | non-structured | non-structured |
| Non-Structured | 0.0353 | 0.0078 | 1 | 1 |
| Inverse | 0.1720 | 0.0569 | 4.87 | 7.29 |
| Replica | 0.0940 | 0.7298 | 2.66 | 93.56 |
| Photolithography | 0.1851 | 0.0373 | 5.24 | 4.78 |

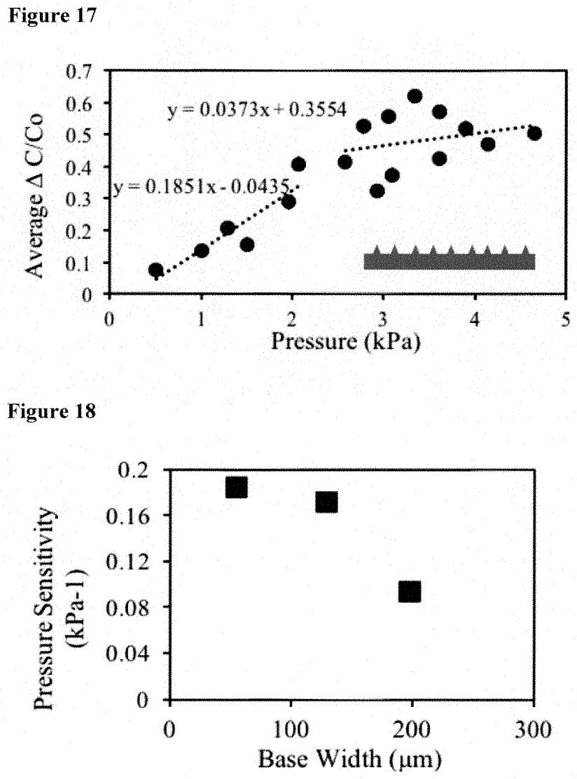

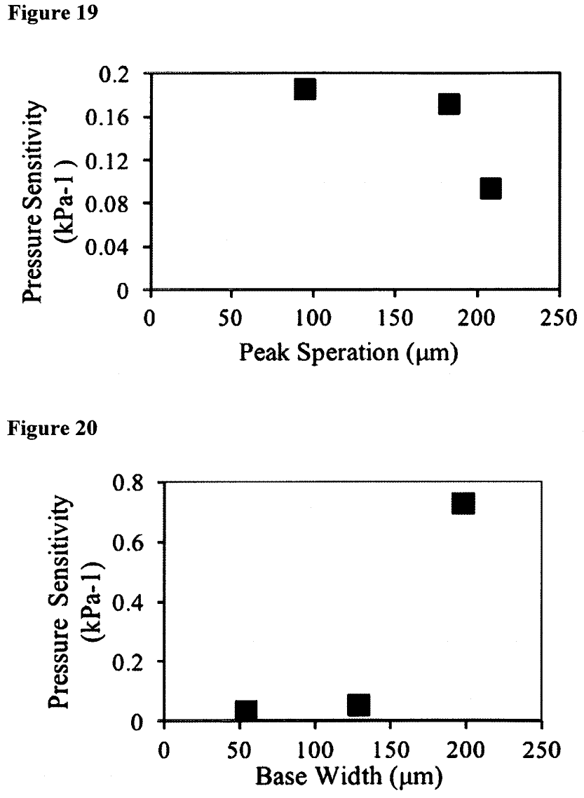

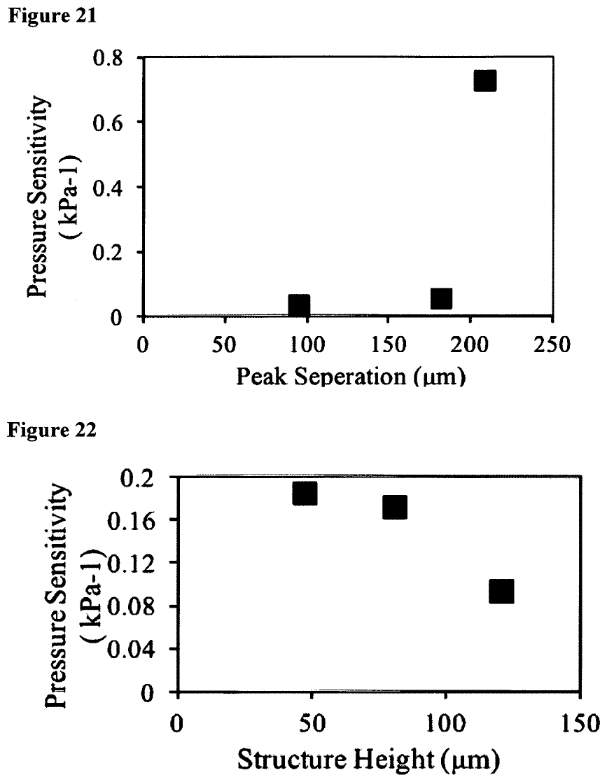

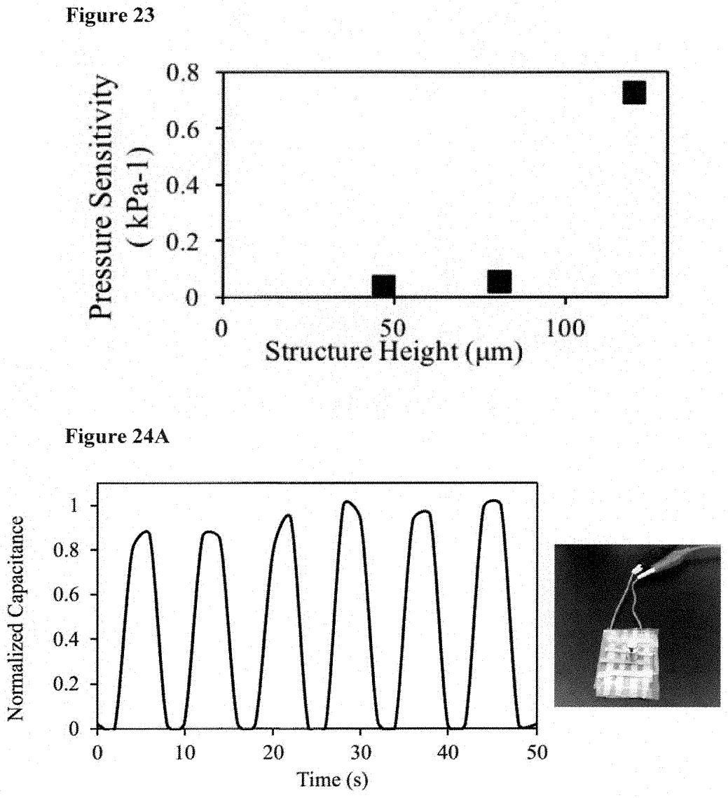

The highest sensitivity at 0.5 kPa<p<3 kPa was achieved with the photolithographic dielectric device, which also had the smallest height and distance between the microstructured features. This greater sensitivity at lower pressure values can be attributed to the small and regular structures, which allows for a maximum compression threshold. In fact, the lower this threshold or height of the structure is, the less change in distance between the plates of the capacitor at pressures that cause maximum compression. At lower pressures, however; the distance change shows a linear relationship with pressure, as seen in FIG. 17. After the maximum compression of these structures at approximately 3 kPa, the change in capacitance as a function of pressure is less proportionate because of the maximum compression of the structures being met. The lower pressure sensitivity of inverse mold is 4.87 times higher than the nonstructured (see Table 2). The photolithographic lower pressure sensitivity (Sₗ) is 5.24 times higher than that of non-structured. The difference between the lower pressure sensitivity (Sₗ) of the photolithographic dielectric structures and the inverse dielectric structures are small (Table 2), that can also be explained by the size and distribution of the structures. Likewise, the small 7.4% difference between the lower pressure sensitivity of the photolithographic dielectric structures and the inverse dielectric structures can also be explained by the size and distribution of the structures.

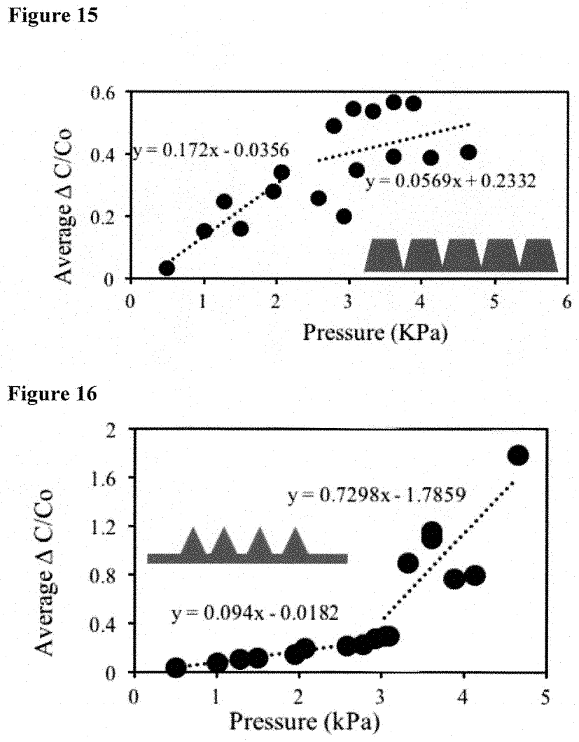

Compared to the replica dielectric structures, which show larger and less distributed structures, the inverse structures show greater distribution with smaller sized features in terms of height and base width. The smaller size and greater distribution of the inverse dielectric structures can be paralleled to a similar relationship than that of the photolithographic dielectric structures, which showed the highest sensitivity at lower pressures. This result confirms the relationship between the size and distribution of the microstructures, where the smaller the size and the closer the distance between peaks results in higher sensitivity at lower pressures, as seen in FIGS. 14 and 15. This also suggests that, as the size of the structures decreases and as the pressure points become more distributed, the sensitivity of the sensor at lower pressures applied increases.

An opposite relationship was also observed for replica dielectric structures, which has the largest base size and the greatest distance between features. As shown in FIGS. 16 and 17, replica dielectric structures showed the greatest sensitivity at 3 kPa<p<6 kPa. Since the base widths and heights of the structures were the largest, and individual structures were more interspaced compared to the other dielectrics used, the pressure points created allowed for greater compression proportional to the pressure applied. Lastly, the greater the size of the replica dielectric structure base width and height can explain the sensitivity at higher pressures, due to an increased volume available for elastic deformation to occur. As the mechanical energy is distributed from the tip of the structure down to its base, the larger the base and height of the structure become the greater the range for physical deformation. Therefore, the microstructures can respond to higher pressures as there is greater volume available to mechanically respond. This is also in agreement with the results shown in FIG. 16, where low pressures resulted in small changes in capacitance change detected. However, at higher pressures (3 kPa<p<6 kPa) the structures experienced greater compression that resulted in higher changes in capacitance, especially at pressures greater than 4.5 kPa.

The inverse and replica dielectric structures were shown to lead to an increased pressure sensitivity when compared to photolithographically-produced dielectric, especially at pressures greater than 3 kPa. Furthermore, the replica structures showed the highest sensitivity when incorporated into the device compared to the inverse and photolithographic samples at pressures between 3 kPa and 6 kPa. The largest increase was found between the replica dielectric structures and the non-structured dielectric structures at the higher pressure range (3-6 kPa), which was calculated to be about 93 times increase (Table 2). This finding is particularly promising for detecting higher pressure ranges, such as three-dimensional pressure detection for bed sore prevention in hospitalized patients, prosthetic-limb interface detection and orthotic applications, etc. Most importantly, these findings suggest the replica and inverse tape ribbon molded dielectrics are able to increase the sensitivity of flexible, capacitance-based pressure sensors by using a more efficient, and inexpensive method of microstructure incorporation than current techniques.

### D. Dynamic Measurements and Gait Analysis

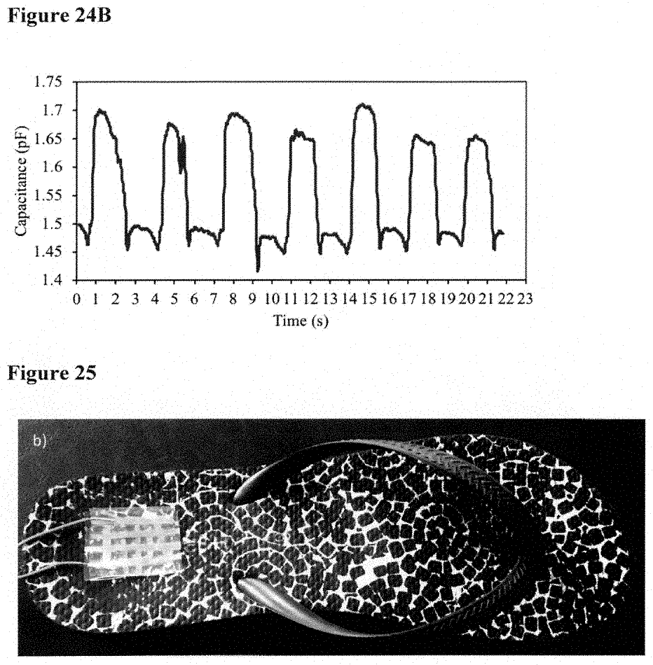

Upon characterizing the devices' sensitivity to various pressure ranges, further dynamic loading and capacitance testing was performed to analyze the ability to efficiently respond to a time-varied mechanical loading. A 50 g standardized weight was dynamically placed on top of the device for 2 seconds and then removed for 2 seconds while being connected to an LCR meter for capacitance value recordings as a function of time. Capacitance was recorded at 2 second intervals. This cycle was repeated for 6 cycles and then normalized. The results obtained are summarized in FIG. 24A. In another experiment, similarly, A 50 g standardized weight was dynamically placed on top of the device while being connected to a ZM2372 (NF Corp.) precision LCR meter for capacitance value recordings as a function of time, Capacitance was recorded at 15 millisecond intervals. This cycle was repeated for 7 cycles. The results obtained are summarized in FIG. 24B. The results showed device sensitivity in dynamic measurements, particularly important for the development of novel stretchable electronics.

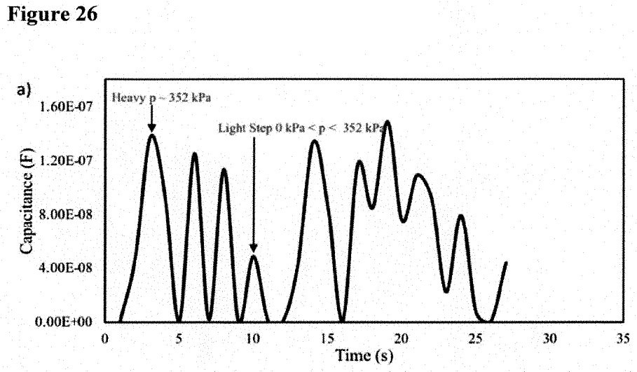

As proof of principal toward that goal, the sensor was incorporated into the heel of a shoe and used to record the capacitance change as a function of time during walking, as seen in FIG. 25. Capacitance values were recorded during a 25 second walking period where the weight registered to the sensor varied between 0 kPa and 352 kPa during the recordings. After 15 seconds of recording standard walking pressure changes within the heel of the shoe, the foot remained grounded and the knee was bent to alter the pressure distribution along the sensor as a function of time. Normalized results are illustrated in FIG. 26, and indicate the success of the device to efficiently detect dynamic pressure changes as a part of a gait analysis device. Moreover, to test their applicability, a sensor array in the insole incorporated the flexible sensor as a pressure detecting shoe insole for gait analysis where the change in pressure during static and dynamic standing and walking activity. The results obtain for this application are summarized in FIG. 26, where zero capacitance on the vertical axis represents when the feet are on the ground. The sensor shoe assembly is shown in FIG. 25. As seen in FIG. 26, at the beginning equal pressure walking steps shows repeating peaks, lightly pressured steps shown small peak whereas high pressured steps showed higher peaks.

In conclusion, a comparative study of various PDMS-based flexible pressure sensors, fabricated using four different structures was performed. Different patterning methods were utilized for incorporating flexible surface microstructures on the PDMS layer including (i) inverse mold, (ii) replica mold, (iii) photolithographic and (iv) non-shaped microstructures. Our results show a strong dependence of the pressure sensitivity versus the patterning method utilized. Dielectric layers patterned from a simple tape molding procedure (replica and inverse tape molded structures) were used as a dielectric within a flexible, capacitance-based pressure sensor, and showed an increased pressure sensitivity at higher pressure regimes (3 kpa<p<6 kPa), when compared to the photolithographic structured dielectric. Importantly, the replica structured dielectric produced the highest device sensitivity of 0.7298 kPa⁻¹ at pressures greater than 3 kPa and less than 6 kPa. Additionally, the inverse dielectric structures based on the initial tape mold, produced a good sensitivity when compared to the photolithographic dielectric, at pressures greater than 0.5 kPa and less than 3 kPa. These results suggest the importance of microstructures for the production of sensors with improved sensitivity. This work also optimizes a method to achieve high pressure sensitivity in flexible polymer-based sensors without the need for expensive and time-consuming methods such as photolithography. The ease of fabrication and malleability of the components used to fabricate these devices provides for a convenient yet widely applicable device for real time health and rehabilitation monitoring.

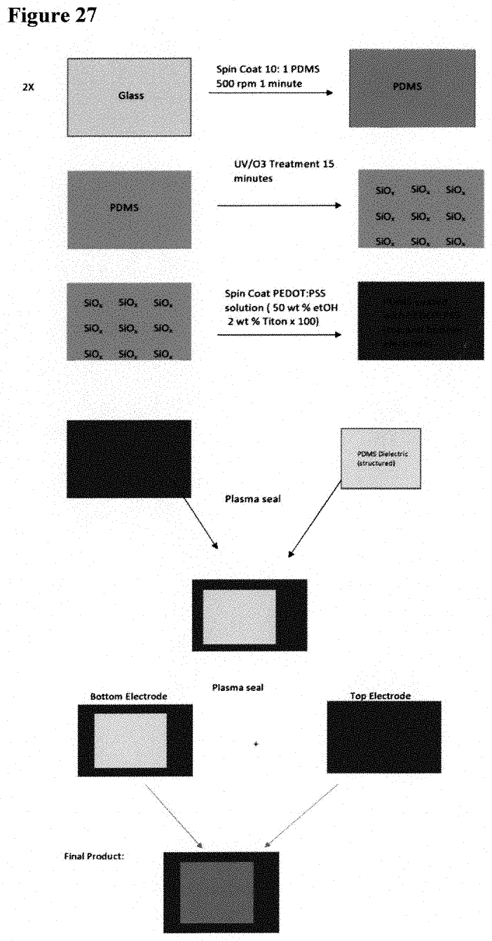

FIG. 27 shows a scheme for another method in accordance with a preferred embodiment of the present invention. The method includes spin coating a glass substrate with 10:1 weight ratio of PDMS and a crosslinking agent and subjecting the coated glass substrate to rotary drying at 500 rpm for 1 minute. The dried PDMS coated glass substrate is then subject to UV and 03 treatment for 15 minutes to form a SiOₓ layer thereon, and which is then spin coated with poly(3,4-ethylenedioxythiophene) polystyrene sulfonate (PEDOT:PSS) solution with 50 weight % EtOH and 2 weight % Titon x100 to obtain a PDMS layer with PEDOT:PSS, forming the top and bottom electrode layer. A PDMS dielectric layer is then plasma sealed to one PEDOT:PSS coated PDMS glass substrate as prepared before, and another PEDOT:PSS coated PDMS glass substrate is plasma sealed to the dielectric layer, such that the dielectric layer is disposed between the glass substrates. During the method, the glass substrate may be removed at any step after spin coating PDMS thereon.

While, the invention has been described with reference to preferred embodiments, the invention is not or intended by the applicant to be so limited. A person skilled in the art would readily recognize and incorporate various modifications, additional elements and/or different combinations of the described components consistent with the scope of the invention as described herein.

The following references are incorporated herein by reference:
[1] W. H. Ko, J. Hynecek, S. F. Boettcher, Development of a Miniature Pressure Transducer for Biomedical Applications, IEEE Trans. Electron Devices. 26 (1979) 1896-1905. doi:10.1109/T-ED.1979.19793.
[2] K. F. Lei, K. F. Lee, M. Y. Lee, Development of a flexible PDMS capacitive pressure sensor for plantar pressure measurement, Microelectron. Eng. 99 (2012) 1-5. doi: 10.1016/j.mee.2012.06.005.
[3] G. Schwartz, B. C. K. Tee, J. Mei, A. L. Appleton, D. H. Kim, H. Wang, Z. Bao, Flexible polymer transistors with high pressure sensitivity for application in electronic skin and health monitoring, Nat. Commun. 4 (2013) 1858-1859. doi:10.1038/ncomms2832.
[4] M. S. Suen, Y. C. Lin, R. Chen, A flexible multifunctional tactile sensor using interlocked zinc oxide nanorod arrays for artificial electronic skin, Sensors Actuators, A Phys. 269 (2018) 574-584. doi:10.1016/j.sna.2017.11.053.
[5] B. Y. Lee, J. Kim, H. Kim, C. Kim, S. D. Lee, Low-cost flexible pressure sensor based on dielectric elastomer film with micro-pores, Sensors Actuators, A Phys. 240 (2016) 103-109. doi:10.1016/j.sna.2016.01.037.
[6] K. Sasagawa, J. Narita, Development of thin and flexible contact pressure sensing system for high spatial resolution measurements, Sensors Actuators, A Phys. 263 (2017) 610-613. doi:10.1016/j.sna.2017.07.024.
[7] D. H. Ho, Q. Sun, S. Y. Kim, J. T. Han, D. H. Kim, J. H. Cho, Stretchable and Multimodal All Graphene Electronic Skin, Adv. Mater. 28 (2016) 2601-2608. doi: 10.1002/adma.201505739.
[8] H. H. Chou, A. Nguyen, A. Chortos, J. W. F. To, C. Lu, J. Mei, T. Kurosawa, W. G. Bae, J. B. H. Tok, Z. Bao, A chameleon-inspired stretchable electronic skin with interactive colour changing controlled by tactile sensing, Nat. Commun. 6 (2015) 1-10. doi:10.1038/ncomms9011.
[9] C. M. Boutry, A. Nguyen, Q. O. Lawal, A. Chortos, S. Rondeau-Gagné, Z. Bao, A Sensitive and Biodegradable Pressure Sensor Array for Cardiovascular Monitoring, Adv. Mater. 27 (2015) 6954-6961. doi:10.1002/adma.201502535.
[10] S: Crea, M. Donati, S. M. M. De Rossi, C. Maria Oddo, N. Vitiello, A wireless flexible sensorized insole for gait analysis, Sensors (Switzerland). 14 (2014) 1073-1093. doi:10.3390/s140101073.
[11] S. J. M. Bamberg, A. Y. Benbasat, D. M. Scarborough, D. E. Krebs, J. a Paradiso, Gait analysis using a shoe-integrated wireless sensor system., IEEE Trans. Inf. Technol. Biomed. 12 (2008) 413-23. doi:10.1109/TITB.2007.899493.
[12] C. Mizelle, M. Rodgers, L. Forrester, Bilateral foot center of pressure measures predict hemiparetic gait velocity, Gait Posture. 24 (2006) 356-363. doi:10.1016/j.gaitpost.2005.11.003.
[13] B. Zhuo, S. Chen, M. Zhao, X. Guo, High Sensitivity Flexible Capacitive Pressure Sensor Using Polydimethylsiloxane Elastomer Dielectric Layer Micro-Structured by 3-D Printed Mold, IEEE J. Electron Devices Soc. 5 (2017) 219-223. doi:10.1109/JEDS.2017.2683558.
[14] W. Deng, X. Huang, W. Chu, Y. Chen, L. Mao, Q. Tang, W. Yang, Microstructure-Based Interfacial Tuning Mechanism of Capacitive Pressure Sensors for Electronic Skin, J. Sensors. 2016 (2016). doi:10.1155/2016/2428305.
[15] S. C. B. Mannsfeld, B. C. K. Tee, R. M. Stoltenberg, C. V. H. H. Chen, S. Barman, B. V. O. Muir, A. N. Sokolov, C. Reese, Z. Bao, Highly sensitive flexible pressure sensors with microstructured rubber dielectric layers, Nat. Mater. 9 (2010) 859-864. doi:10.1038/nmat2834.
[16] B. C. K. Tee, A. Chortos, R. R. Dunn, G. Schwartz, E. Eason, Z. Bao, Tunable flexible pressure sensors using microstructured elastomer geometries for intuitive electronics, Adv. Funct. Mater. 24 (2014) 5427-5434. doi:10.1002/adfm.201400712.
[17] Z. Huang, M. Gao, Z. Yan, T. Pan, S. A. Khan, Y. Zhang, H. Zhang, Y. Lin, Pyramid microstructure with single walled carbon nanotubes for flexible and transparent micro-pressure sensor with ultra-high sensitivity, Sensors Actuators, A Phys. 266 (2017) 345-351. doi:10.1016/j.sna.2017.09.054.
[18] A. Nag, S. C. Mukhopadhyay, J. Kosel, Flexible carbon nanotube nanocomposite sensor for multiple physiological parameter monitoring, Sensors Actuators, A Phys. 251 (2016) 148-155. doi:10.1016/j.sna.2016.10.023.
[19] S. Miller, Z. Bao, Fabrication of flexible pressure sensors with microstructured polydimethylsiloxane dielectrics using the breath figures method, J. Mater. Res. 30 (2015) 3584-3594. doi:10.1557/jmr.2015.334.
[20] W. Deng, X. Huang, W. Chu, Y. Chen, L. Mao, Q. Tang, W. Yang, Microstructure-Based Interfacial Tuning Mechanism of Capacitive Pressure Sensors for Electronic Skin, J. Sensors. 2016 (2016). doi:10.1155/2016/2428305.
[21] J. C. Lotters, W. Olthuis, P. H. Veltink, P. Bergveld, Polydimethylsiloxane, a photocurable rubberelastic polymer used as spring material in micromechanical sensors, Microsyst. Technol. 3 (1997) 64-67. doi:10.1007/s005420050057.
[22] O. Atalay, A. Atalay, J. Gafford, C. Walsh, A Highly Sensitive Capacitive-Based Soft Pressure Sensor Based on a Conductive Fabric and a Microporous Dielectric Layer, Adv. Mater. Technol. 3 (2018) 1-8. doi:10.1002/admt.201700237.
[23] M. L. Hammock, A. Chortos, B. C. K. Tee, J. B. H. Tok, Z. Bao, 25th anniversary article: The evolution of electronic skin (E-Skin): A brief history, design considerations, and recent progress, Adv. Mater. 25 (2013) 5997-6038. doi:10.1002/adma.201302240.
[24] C. L. Choong, M. B. Shim, B. S. Lee, S. Jeon, D. S. Ko, T. H. Kang, J. Bae, S. H. Lee, K. E. Byun, J. Im, Y. J. Jeong, C. E. Park, J. J. Park, U. I. Chung, Highly stretchable resistive pressure sensors using a conductive elastomeric composite on a micropyramid array, Adv. Mater. 26 (2014) 3451-3458. doi:10.1002/adma.201305182.
[25] Y. Mi, Y. Chan, D. Trau, P. Huang, E. Chen, Micromolding of PDMS scaffolds and microwells for tissue culture and cell patterning: A new method of microfabrication by the self-assembled micropatterns of diblock copolymer micelles, Polymer (Guildf). 47 (2006) 5124-5130. doi:10.1016/j.polymer.2006.04.063.
[26] I. D. Johnston, D. K. McCluskey, C. K. L. Tan, M. C. Tracey, Mechanical characterization of bulk Sylgard 184 for microfluidics and microengineering, J. Micromechanics Microengineering. 24 (2014). doi:10.1088/0960-1317/24/3/035017.
[27] N. Q. Balaban, U. S. Schwarz, D. Riveline, P. Goichberg, G. Tzur, I. Sabanay, D. Mahalu, S. Safran, A. Bershadsky, L. Addadi, B. Geiger, Force and focal adhesion assembly: a close relationship studied using elastic micropatterened substrates, Nat. Cell Biol. 3 (2001) 466-472. doi:10.1038/35074532 T4—A close relationship studied using elastic micropatterned substrates PM—11331874 M4—Citavi.
[28] A. Urrios, C. Parra-Cabrera, N. Bhattacharjee, A. M. Gonzalez-Suarez, L. G. Rigat-Brugarolas, U. Nallapatti, J. Samitier, C. A. Deforest, F. Posas, J. L. Garcia-Cordero, A. Folch, 3D-printing of transparent bio-microfluidic devices in PEG-DA, Lab Chip. 16 (2016) 2287-2294. doi:10.1039/c61c00153j.
[29] D. J. Lipomi, M. Vosgueritchian, B. C. K. Tee, S. L. Hellstrom, J. A. Lee, C. H. Fox, Z. Bao, Skin-like pressure and strain sensors based on transparent elastic films of carbon nanotubes, Nat. Nanotechnol. 6 (2011) 788-792. doi:10.1038/nnano.2011.184.
[30] B. B. Narakathu, A. Eshkeiti, A. S. G. Reddy, M. Rebros, E. Rebrosova, M. K. Joyce, B. J. Bazuin, M. Z. Atashbar, A novel fully printed and flexible capacitive pressure sensor, Proc. IEEE Sensors. (2012) 26-29. doi:10.1109/ICSENS.2012.6411354.
[31] A. Eshkeiti, S. Emamian, S. G. R. Avathu, B. B. Narakathu, M. J. Joyce, M. K. Joyce, B. J. Bazuin, M. Z. Atashbar, Screen printed flexible capacitive pressure sensor, IEEE SENSORS 2014 Proc. (2014) 1192-1195. doi:10.1109/ICSENS.2014.6985222.
[32] B. Zhuo, S. Chen, X. Guo, Micro structuring polydimethylsiloxane elastomer film with 3D printed mold for low cost and high sensitivity flexible capacitive pressure sensor, 2017 IEEE Electron Devices Technol. Manuf. Conf. EDTM 2017—Proc. 8 (2017) 148-149. doi:10.1109/EDTM.2017.7947545.
[33] D. Maddipatla, B. B. Narakathu, M. M. Ali, A. A. Chlaihawi, M. Z. Atashbar, Printed and Flexible Pressure Sensor, (2017).
[34] D. Grlbner, M. Tintelott, G. Dumstorff, W. Lang, Low-Cost Thin and Flexible Screen-PrintedPressure Sensor, Proceedings. 1 (2017) 616. doi: 10.3390/proceedings1040616.
[35] B. Grzybowski, D. Qin, R. Haag, G. M. Whitesides, Elastomeric optical elements with deformable surface topographies: Applications to force measurements, tunable light transmission and light focusing, Sensors Actuators, A Phys. 86 (2000) 81-85. doi:10.1016/S0924-4247(00)00421-0.
[36] I. W. Moran, D. F. Cheng, S. B. Jhaveri, K. R. Carter, High-resolution soft lithography of thin film resists enabling nanoscopic pattern transfer, Soft Matter. 4 (2007) 168-176. doi:10.1039/b711506g.
[37] H. Kou, L. Zhang, Q. Tan, G. Liu, W. Lv, F. Lu, H. Dong, J. Xiong, Wireless flexible pressure sensor based on micro-patterned Graphene/PDMS composite, Sensors Actuators, A Phys. 277 (2018) 150-156. doi:10.1016/j.sna.2018.05.015.
[38] Z. Wang, A. A. Volinsky, N. D. Gallant, Crosslinking effect on polydimethylsiloxane elastic modulus measured by custom-built compression instrument, J. Appl. Polym. Sci. 131 (2014) 1-4. doi:10.1002/app.41050.
[39] J. Lejeune, V. Le Houérou, T. Chatel, H. Pelletier, C. Gauthier, R. Mülhaupt, Creep and recovery analysis of polymeric materials during indentation tests, Eur. J. Mech. A/Solids. 68 (2018) 1-8. doi:10.1016/j.euromechsol.2017.10.003.
[40] E. A. Al-Fakih, N. A. Abu, Osman, F. R. Mahamd Adikan, A. Eshraghi, P. Jahanshahi, Development and Validation of Fiber Bragg Grating Sensing Pad for Interface Pressure Measurements Within Prosthetic Sockets, IEEE Sens. J. 16 (2016) 965-974. doi:10.1109/JSEN.2015.2495323.
[41] H. Wong, J. Kaufman, B. Baylis, J. M. Conly, D. B. Hogan, H. T. Stelfox, D. A. Southern, W. A. Ghali, C. H. Ho, Efficacy of a pressure-sensing mattress cover system for reducing interface pressure: Study protocol for a randomized controlled trial, Trials. 16 (2015) 1-11. doi:10.1186/s13063-015-0949-x.

We claim:

1. A method for preparing a capacitive pressure sensor, the sensor comprising a pair of conductive plate layers and a dielectric layer disposed therebetween, the dielectric layer comprising a dielectric polymer formed with a polymerization mixture fluid, wherein the method comprises placing the polymerization mixture fluid over a mold surface having a first three dimensional pattern thereon to form the dielectric polymer, thereby forming a second three dimensional pattern on a surface of the dielectric polymer complementary to the first three dimensional pattern.

2. The method of claim 1, wherein the dielectric polymer comprises a crosslinked polydimethylsiloxane polymer, and the polymerization mixture fluid comprises a pre-polymer mixture comprising at least one or more silicon monomers, and a crosslinking agent selected for crosslinking a linear polydimethylsiloxane polymer to form the crosslinked polydimethylsiloxane polymer, wherein the weight ratio of the pre-polymer mixture to the crosslinking agent in the polymerization mixture fluid is between about 10:1 and about 30:1.

3. The method of claim 1, wherein said method further comprises curing the polymerization mixture fluid over the mold surface at a curing temperature between about 40° C. and about 80° C. for between about 30 minutes and 4 hours.

4. The method of claim 3, wherein the method further comprises degassing the polymerization mixture fluid in a vacuum desiccator prior to said curing the polymerization mixture fluid, and after said curing the polymerization mixture fluid, the method further comprises removing or peeling the dielectric polymer from the mold surface.

5. The method of claim 1, wherein one of the first and second three dimensional patterns comprises a plurality of pyramidal projections extending substantially normal to the mold surface or the surface of the dielectric polymer, and the other one of the first and second three dimensional patterns is shaped for forming the pyramidal projections.

6. The method of claim 5, wherein each said pyramidal projection has a generally triangular pyramid shape having a peak, wherein a peak height of the triangular pyramid shape is between about 80 μm and about 160 μm, a base width of the triangular pyramid shape is between about 160 μm and 240 μm, and/or a distance between two said triangular pyramid shapes is between about 160 μm and 240 μm.

7. The method of claim 1, wherein one of the first and second three dimensional patterns is substantially shaped as shown in FIGS. 5 and 6, and the other one of the first and second three dimensional patterns is substantially shaped as shown in FIGS. 7 and 8.

8. The method of claim 1, wherein the mold surface is provided by an adhesive tape having the first three dimensional pattern thereon, the method further comprising dissolving or removing an adhesive portion of the adhesive tape prior to said placing the polymerization mixture fluid over the mold surface.

9. The method of claim 1, wherein the mold surface is provided by a polymeric mold formed by placing a second polymerization mixture fluid over an adhesive tape having a third three dimensional pattern thereon, an adhesive portion of the adhesive tape having been removed or dissolved prior to said placing the second polymerization mixture fluid over the adhesive tape, wherein the third three dimensional pattern is shaped for forming the first three dimensional pattern.

10. The method of claim 9, wherein the second polymerization mixture fluid is cured over the adhesive tape at a curing temperature between about 40° C. and about 80° C. for between about 30 minutes and 4 hours to form the polymeric mold, and the polymeric mold is subject to vapor deposition of perfluorooctyltrichlorosilane (FOTS) prior to said placing the polymerization mixture fluid over the mold surface.

11. The method of claim 1, wherein the method further comprises placing the dielectric layer between the conductive plate layers, wherein each said conductive plate layer comprises a polydimethylsiloxane polymer plate having a plurality of generally parallel elongate conductive tapes coupled thereto, and wherein the conductive plate layers are oriented relative to each other to place the conductive tapes coupled to one of the polydimethylsiloxane polymer plate generally orthogonal to the conductive tapes coupled to the other one of the polydimethylsiloxane polymer plate.

12. The method of claim 1, wherein the polydimethylsiloxane polymer plate is coated with poly(3,4-ethylenedioxythiophene) polystyrene sulfonate (PEDOT:PSS), said method further comprising plasma sealing the dielectric layer to the conductive plate layers.

13. A capacitive pressure sensor comprising a pair of conductive plate layers and a dielectric layer disposed therebetween, the dielectric layer comprising a polydimethylsiloxane polymer and the conductive plate layers each comprising a polydimethylsiloxane polymer plate, wherein the dielectric layer is prepared with a method comprising placing a polymerization mixture fluid over a mold surface having a first three dimensional pattern thereon to form the polydimethysiloxane polymer, thereby forming a second three dimensional pattern on a surface of the polydimethylsiloxane polymer complementary to the first three dimensional pattern, and wherein one of the first and second three dimensional patterns comprises a plurality of projections extending substantially normal to the mold surface or the surface of the polydimethylsiloxane polymer, and the other one of the first and second three dimensional patterns is shaped for forming the projections.

14. The capacitive pressure sensor of claim 13, wherein each said projection has a generally triangular pyramid shape having a peak, wherein a peak height of the triangular pyramid shape is between about 80 μm and about 160 μm, a base width of the triangular pyramid shape is between about 160 μm and 240 μm, and/or a distance between two said triangular pyramid shapes is between about 160 μm and 240 μm.

15. The capacitive pressure sensor of claim 13, wherein one of the first and second three dimensional patterns is substantially shaped as shown in FIGS. 5 and 6, and the other one of the first and second three dimensional patterns is substantially shaped as shown in FIGS. 7 and 8.

16. The capacitive pressure sensor of claim 13, wherein the polydimethylsiloxane polymer plate has a plurality of generally parallel elongate conductive tapes coupled thereto, and wherein the conductive plate layers are oriented relative to each other to place the conductive tapes coupled to one of the polydimethylsiloxane polymer plate generally orthogonal to the conductive tapes coupled to the other one of the polydimethylsiloxane polymer plate.

17. The capacitive pressure sensor of claim 16, wherein the polydimethylsiloxane polymer plate is coated with poly(3,4-ethylenedioxythiophene) polystyrene sulfonate (PEDOT:PSS), and the dielectric layer is plasma sealed to the conductive plate layers.

18. The capacitive pressure sensor of claim 13, wherein the polydimethylsiloxane polymer comprises a crosslinked polydimethylsiloxane polymer, and the polymerization mixture fluid comprises a pre-polymer mixture comprising at least one or more silicon monomers, and a crosslinking agent selected for crosslinking a linear polydimethylsiloxane polymer to form the crosslinked polydimethylsiloxane polymer, wherein the weight ratio of the pre-polymer mixture to the crosslinking agent in the polymerization mixture fluid is between about 10:1 and about 30:1.

19. The capacitive pressure sensor of claim 13, wherein said method further comprises curing the polymerization mixture fluid over the mold surface at a curing temperature between about 40° C. and about 80° C. for between about 30 minutes and 4 hours.

20. The capacitive pressure sensor of claim 19, wherein the method further comprises degassing the polymerization mixture fluid in a vacuum desiccator prior to said curing the polymerization mixture fluid, and after said curing the polymerization mixture fluid, the method further comprises removing or peeling the dielectric polymer from the mold surface.

21. The capacitive pressure sensor of claim 13, wherein the mold surface is provided by an adhesive tape having the first three dimensional pattern thereon, the method further comprising dissolving or removing an adhesive portion of the adhesive tape prior to said placing the polymerization mixture fluid over the mold surface.

22. The capacitive pressure sensor of claim 13, wherein the mold surface is provided by a polymeric mold formed by placing a second polymerization mixture fluid over an adhesive tape having a third three dimensional pattern thereon, an adhesive portion of the adhesive tape having been removed or dissolved prior to said placing the second polymerization mixture fluid over the adhesive tape, wherein the third three dimensional pattern is shaped for forming the first three dimensional pattern.

23. The capacitive pressure sensor of claim 22, wherein the second polymerization mixture fluid is cured over the adhesive tape at a curing temperature between about 40° C. and about 80° C. for between about 30 minutes and 4 hours to form the polymeric mold, and the polymeric mold is subject to vapor deposition of perfluorooctyltrichlorosilane (FOTS) prior to said placing the polymerization mixture fluid over the mold surface.
